(19) United States
(12) Patent Application Publication
(10) Pub. No.: US 2018/0304585 A1
(43) Pub. Date: Oct. 25, 2018

(54) MULTILAYER BARRIER COATINGS

(71) Applicants: Naota NUGIYAMA, Tokyo (JP); Jiro HATTORI, Atsugi-city (JP); Richard J. POKORNY, Maplewood, MN (US); Moses M. DAVID, Woodbury, MN (US); Xue-hua CHEN, Shanghai (CN); Shinya NAKAJIMA, Hachioji-city (JP); Takehiro MITSUDA, Kanagawa (JP); Brant U. KOLB, Afton, MN (US); 3M INNOVATIVE PROPERTIES COMPANY, St. Paul, MN (US)

(72) Inventors: Naota SUGIYAMA, Tokyo (JP); Jiro HATTORI, Atsugi-city (JP); Richard J. POKORNY, Maplewood, MN (US); Moses M. DAVID, Woodbury, MN (US); Xue-hua CHEN, Shanghai (CN); Shinya NAKAJIMA, Hachioji-city (JP); Takehiro MITSUDA, Kanagawa (JP); Brant U. KOLB, Afton, MN (US)

(21) Appl. No.: 15/763,339

(22) PCT Filed: Sep. 30, 2015
(86) PCT No.: PCT/CN2015/091277

§ 371 Date: Mar. 26, 2018

(51) Int. Cl. B32B 15/08; B32B 27/28; C23C 14/22; C08L 83/06

(52) U.S. Cl. CPC B32B 15/08; B32B 27/283; C23C 14/221; B82Y 30/00; B32B 2457/202; B32B 2457/206; C08L 2203/20; C08L 83/06

(57) ABSTRACT

Multilayer barrier coatings or films and methods of making the same are provided. The coatings or films include a hardcoat layer (122) including nanoparticles hosted by a binder, and a barrier layer (124) directly disposed on a major surface (122s) of the hardcoat layer (122). The binder includes one or more silicone (meth)acrylate additives.

### TECHNICAL FIELD

The disclosure relates to multilayer barrier coatings including a hardcoat layer and a barrier layer.

Many articles such as organic light emitting diodes (OLEDs), organic and inorganic photovoltaics (PV), quantum dot display (QDD) devices require protection from oxygen and/or water ingress. Barrier coatings or films have been developed to protect articles or devices in various industrial fields such as food package, medical storage, electronic industry, etc. Available barrier coatings or films use metals or glasses to protect the devices.

### SUMMARY

There is a need to improve properties (e.g., flexibility, optical properties, anti-scratching, anti-cracking, moisture barrier performance, etc.) of barrier coatings or films. Briefly, in one aspect, the present disclosure describes a multilayer barrier film including a hardcoat layer comprising nanoparticles hosted by a binder. The binder includes one or more silicone (meth)acrylate additives. A barrier layer is directly disposed on a major surface of the hardcoat layer.

In another aspect, the present disclosure describes a device that includes a multilayer barrier film described herein. The device further includes a cover panel and an optically clear adhesive layer. The multilayer barrier film is disposed between the cover panel and the optically clear adhesive layer, and configured to prevent diffusion moisture or oxygen from the cover panel to the optically clear adhesive layer. In some embodiments, the device is a liquid crystal display (LCD).

In another aspect, the present disclosure describes a method of making a multilayer barrier file. The method includes providing a mixture comprising nanoparticles and one or more curable binder materials, and curing the binder materials to provide a hardcoat layer. The hardcoat layer includes the nanoparticles hosted by a binder. The binder includes one or more silicone (meth)acrylate additives. A barrier layer is provided directly disposed on the hardcoat layer.

Various unexpected results and advances are obtained in exemplary embodiments of the disclosure. One such advantage of exemplary embodiments of the present disclosure is that by adding one or more silicone (meth)acrylate additives into a hardcoat layer, the obtained multilayer barrier coatings exhibit excellent durability (e.g., substantially crack-free and scratch-fee). In general, the barrier performance of a barrier film is proportional to thickness of a barrier layer (e.g., a plasma deposited barrier layer). For example, a one micron thick plasma deposited barrier layer may provide WVTR of 1×10⁻⁴ g/m²/day. However, cracks easily occur on thicker barrier layers in the absence of a hardcoat layer described herein. Some embodiments described herein address this issue on barrier film application, and provide durable barrier films for various applications. In particular, adding silicone (meth)acrylate (e.g., PDMS acrylate) in the hardcoat layer can provide the advantage of improved durability and measure barrier performance. For example, the silicone (meth)acrylate may improve adhesion of the barrier layer to the hardcoat layer. Also, the silicone (meth)acrylate may act as an etch mask, preventing possible damage during the following process of forming the barrier layer thereon (e.g., plasma induced damage, etching and the consequential roughening of the underlying hard coat layer, etc.).

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1 is a schematic cross-sectional view of a multilayer barrier stack, according to one embodiment.

FIG. 2 is a schematic cross-sectional view of a device including the multilayer barrier stack of FIG. 1, according to another embodiment.

FIG. 3 is a schematic view of roll to roll plasma chemical vapor deposition equipment for making a barrier layer, according to one embodiment.

FIG. 4 illustrate WVTR values under 4° C. 90% RH as a function of time for Examples with various additive amount of “Tegorad 2500” (polydimethyl siloxane acrylate).

FIG. 5 is an SEM cross sectional view of a multilayer barrier slack, according to one embodiment.

FIG. 6 illustrates WVTR values under 40° C. 90% RH as a function of time for Examples before and after steelwool and cotton abrasion testing.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

Certain terms are used throughout the description and the claims that, while for the most part are well known, may require some explanation. It should be understood that:

The term “homogenous” means exhibiting only a single phase of matter when observed at a macroscopic scale.

The term “(co)polymer” or “(co)polymers” includes homopolymers and copolymers, as well as homopolymers or copolymers that may be formed in a miscible blend, e.g., by coextrusion or by reaction, including, e.g., transesterification. The term “copolymer” includes random, block and star (e.g. dendritic) copolymers.

The term “(meth)acrylate” with respect to a monomer or oligomer means a vinyl-functional alkyl ester formed as the reaction product of an alcohol with an acrylic or a methacrylic acid.

The term “diamond-like glass” (DLG) refers to substantially or completely amorphous glass including carbon and silicon, and optionally including one or more additional components selected from the group including hydrogen, nitrogen, oxygen, fluorine, sulfur, titanium, and copper. Other elements may be present in certain embodiments. The amorphous diamond-like glass films may contain clustering of atoms to give it a short-range order but are essentially void of medium and long range ordering to lead to micro or macro crystallinity which can adversely scatter radiation having wavelengths of from 180 nanometers (nm) to 800 nm.

The term “adjoining” with reference to a particular layer means joined with or attached to another layer, in a position wherein the two layers are either next to (i.e., adjacent to) and directly contacting each other, or contiguous with each other but not in direct contact (i.e., there are one or more additional layers intervening between the layers).

By using terms of orientation such as “atop”, “on”, “covering”, “uppermost”, “underlying” and the like for the location of various elements in the disclosed coated articles, we refer to the relative position of an element with respect to a horizontally-disposed, upwardly-facing substrate. However, unless otherwise indicated, it is not intended that the substrate or articles should have any particular orientation in space during or after manufacture.

By using the term “overcoated” to describe the position of a layer with respect to a substrate or other element of an article of the present disclosure, we refer to the layer as being atop the substrate or other element, but not necessarily contiguous to either the substrate or the other element.

By using the term “separated by” to describe the position of a layer with respect to other layers, we refer to the layer as being positioned between two other layers but not necessarily contiguous to or adjacent to either layer.

The terms “about” or “approximately” with reference to a numerical value or a shape means +/− five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transits more radiation (e.g., visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the contest clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

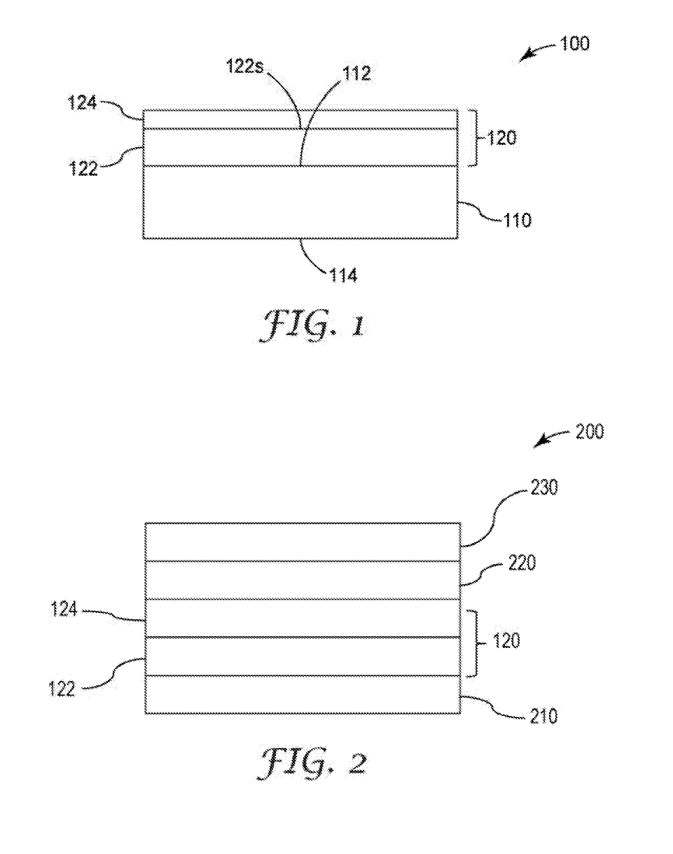

FIG. 1 is a schematic cross-sectional view of a multilayer barrier assembly 100, according to one embodiment. The multilayer barrier assembly 100 incudes a barrier stack 120 disposed on a flexible substrate 110. In some embodiments, the barrier stack 120 and the flexible substrate 110 may form an integral protective layer. In some embodiments, the barrier stack 120 can be released from the substrate 110 before use. The barrier stack 120 includes a hardcoat layer 122 and a barrier layer 124 arranged in a layered structure. The flexible substrate has a first major surface 112 and a second major surface 114 opposite the first major surface 112. It is to be understood that the substrate may be rigid or semi-rigid instead of flexible. In the depicted embodiment, the hardcoat layer 122 is directly disposed on the first major surface 112 of the flexible substrate 110. The hardcoat layer 122 includes a major surface 122s opposite the first major surface 112 of the flexible substrate 110. The barrier layer 124 is directly disposed on the major surface 122s.

The hardcoat layer 122 and the barrier layer 124 can be called a dyad. While only one dyad (i.e., the hardcoat layer 122 and the barrier layer 124 in FIG. 1) is shown for the barrier stack 120, it is to be understood that the barrier stack 120 may include additional alternating hardcoat layers and barrier layers disposed on the first major surface 112 of the flexible substrate 110.

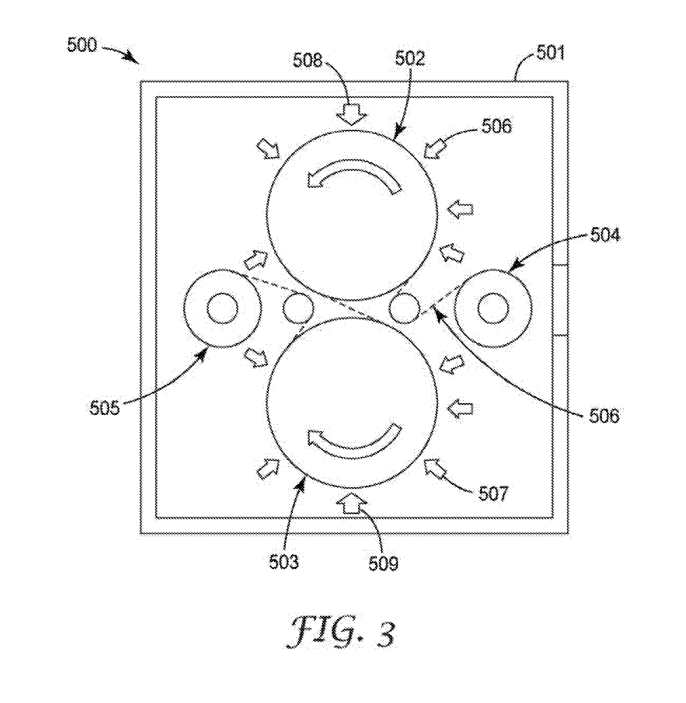

It is to be understood that in some embodiments, the flexible substrate 110 may be optional. For example, the substrate 110 may include a release coating thereon which allows the barrier stack 120 to be released without any significant damage. The barrier stack 120 may be removable from the substrate 110 and applied to any suitable devices. FIG. 2 illustrates a device that makes use of the barrier stack 120, which will be discussed further below. In some embodiments, the substrate may be a portion of a device, and the hardcoat layer 122 can be directly disposed on the device (e.g., a polarizer).

The substrate 110 can include thermoplastic films such as polyesters (e.g., PET), polyacrylates (e.g., polymethyl methacrylate), polycarbonates, polypropylenes, high or low density poloyethylenes, polyethylene naphthalates, polysulfones, polyether sulfones, polyurethanes, polyamides, polyvinyl butyral, polyvinyl chloride, polyvinylidene difluoride and polyethylene sulfide, and thermoset films such as cellulose derivatives, polyimide, polyimide benzoxazole, and poly benzoxazole.

Other suitable materials for the substrate include chlorotrifluoroethylene-vinylidene fluoride copolymer (CTFE/VDF), ethylene-chlorotrifluoroethylene copolymer (ECTFE), ethylene-tetrafluoroethylene copolymer (ETFE), fluorinated ethylene-propylene copolymer (FEP), polychlorotrifluoroethylene (PCTFE), perfluoroalkyl-tetrafluoroethylene copolymer (PFA), polyatetrafluoroethylene (PTFE), polyvinylidene fluoride (PVDF), polyvinyl fluoride (PVF), tetrafluoroethylene-hexafluoropropylene copolymer (TFE/HFP), tetrafluoroethylene-hexafluoropropylene-vinylidene fluoride terpolymer (THV), polychlorotrifluoroethylene (PCTFE), hexafluoropropylene-vinylidene fluoride copolymer (HFP/VDF), tetrafluoroethylene-propylene copolymer (TFE/P), and tetrafluoroethylene-perfluoromethylether copolymer (TFE/PFMc).

Alternative substrates may include materials having a high glass transition temperature (Tg), preferably being heat-stabilized, using heat setting, annealing under tension, or other techniques that will discourage shrinkage up to at least the heat stabilization temperature when the support is not constrained. If the support has not be heat stabilized, then it preferably has a Tg greater than that of polymethyl methacrylate (PMMA, Tg=105° C.). More preferably the support has a Tg of at least about 110° C., yet more preferably at least about 120° C., and more preferably at least about 128° C. Other preferred supports include other heat-stabilized high Tg polyesters, PMMA, styrene/acrylonitrile (SAN, Tg=110° C.), styrene/maleic anhydride (SMA, Tg=115° C.), polyethylene naphthalate (PEN, Tg≤about 120° C.), polyoxymethylene (POM, Tg=about 125° C.), polyvinylnaphthalene (PVN, Tg=about 135° C.), polyetheretherketone (PEEK, Tg=about 145° C.), polyaryletherketone (PAEK, Tg=145° C.), high Tg fluoropolymers (e.g., DYNEON™ HTE terpolymer of hexafluoropropylene, tetrafluoroethylene, and ethylene, Tg=149° C.), polycarbonate (PC, Tg=about 150° C.), poly alpha-methyl styrene (Tg=about 175° C.), polyarylate (PAR, Tg=190° C.), polysulfone (PSul, Tg=about 195° C.), polyphenylene oxide (PPO, Tg=about 200° C.), polyetherimide (PEI, Tb=about 218° C.), polyarylsulfone (PAS, Tg=220° C.), poly ether sulfone (PES, Tg=about 225° C.), polyamideimide (PAI, Tg=275° C.), polyimide (Tg=about 300° C.) and polyphthalamide (heat deflection temp of 120° C.). For application where material costs are important supports made of heat-stabilized polyethylene terephthalate (HSPET) and PEN are especially preferred. For applications where barrier performance is paramount, supports made of more expensive materials may be employed. Preferably the substrate has a thickness of about 0.01 millimeters (mm) to about 1 mm, more preferably about 0.1 mm to about 0.25 mm, more preferably about 0.01 mm to about 0.1 mm, more preferably about 0.01 mm to about 0.05 mm.

A hardcoat layer described herein such as the hardcoat layer 122 of FIG. 1 can be formed from a coating composition including one ore more crosslinkable polymeric materials as polymeric matrix material or binder for hosting nanoparticles. Exemplary binders may include, for example, one or more (meth)acrylic oligomers and/or monomers as binder materials.

In some embodiments, the composition of a hardcoat layer described herein can include one or more crosslinkable acrylate materials such as, for example, pentacrythritol triacrylate, tris(hydroxy ethyl) isocyanurate triacrylate, etc. Especially preferred monomers that can be used to form the hardcoat layer include urethane acrylates (e.g., CN-968, Tg=about 84° C. and CN-983, Tg=about 90° C., both commercially available from Sartomer Co.), isoborynl acrylate (e.g., SR-506, commercially available from Sartomer Co., Tg=about 88° C.), dipentaerythritol pentaacrylates (e.g., SR-399, commercially available from Sartomer Co., Tg=about 90° C.), epoxy acrylates blended with styrene (e.g., CN-120S80, commercially available from Sartomer Co., Tg=about 95° C.), di-trimethylolpropane tetraacrylates (e.g., SR-355, commercially available from Sartomer Co., Tg=about 98° C.), diethylene glycol diacrylates (e.g., SR-230, commercially available from Sartomer Co., Tg=about 100° C.), 1,3-butylene glycol diacrylate (e.g., SR-212, commercially available from Sartomer Co., Tg=about 101° C.), pentaacrylate esters (e.g., SR-9041, commercially available from Sartomer Co., Tg=about 102° C.), pentaerythritol tetraacrylates (e.g., SR-295, commercially available from Sartomer Co., Tg=about 103° C.), pentaerythritol triacylates (e.g., SR-444, commercially available from Sartomer Co., Tg=about 103° C.), ethoxylated (3) trimethylolpropane triacrylates (e.g., SR-454, commercially available from Sartomer Co., Tg=about 103° C.), ethoxylated (3) trimethylolpropane triacrylates (e.g., SR-454HP, commercially available from Sartomer Co., Tg=about %103° C.), alkoxylated trifunctional acrylate esters (e.g., SR-9008, commercially available from Sartomer Co., Tg=about 103° C.), dipropylene glycol diacrylates (e.g., SR-508, commercially available from Sartomer Co., Tg=about 104° C.), neopentyl glycol diacrylated (e.g., SR-247, commercially available from Sartomer Co., Tg=about 107° C.), ethoxylated (4) bisphenol a dimethacrylates (e.g., CD-450 commercially available from Sartomer Co., Tg=about 108° C.), cyclohexane dimethanol diacrylate esters (e.g., CD-406, commercially available from Sartomer Co., Tg=about 110° C.), isobornyl methacrylate (e.g., SR-423, commercially available from Sartomer Co., Tg=about 110° C.), cyclic diacrylates (e.g., IRR-214, commercially available from UCB Chemicals, Tg=about 208° C.),and tris (2-hydroxy ethyl) isocyanurate triacrylate (e.g., SR-368, commercially available from Sartomer Co., Tg=about 272° C.), acrylates of the foregoing methacrylates and methacrylates of the foregoing acrylates.

In some embodiments, the composition of the hardcoat layer 122 can further include one ore more silicon (meth)acrylate additives in a range, for example, from about 0.01 wt % to about 10 wt %. In some embodiments, the content of silicon (meth)acrylate in a hardcoat layer may be no more than 15 wt %, no more than 10 wt %, or no more than 5 wt %. In some embodiments, the content may be no less than 0.005 wt %, no less than 0.01 wt %, no less than 0.02 wt %, or no less than 0.04 wt %. Silicone (meth)acrylate additives generally include a polydimethylsiloxane (PDMS) backbone and an alkoxy sidechain with a terminal (meth)acrylate group. Such silicon (meth)acrylate additives are commercially available from various suppliers such as Tego Chemie under the trade designations “TEGO Rad 2100”, “TEGO Rad 2250”, “TEGO Rad 2300”, “TEGO Rad 2500”, and “TEGO Rad 2700”.

Based on NMR analysis “TEGO Rad 2100” and “TEGO Rad 2500” are believed to have the following chemical structure:

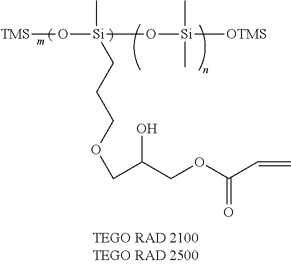

wherein n ranges from 10 to 20 and m ranges from 0.5 to 5.

In some embodiments, a ranges from 14 to 16 and n ranges from 0.9 to 3. The molecular weight typically ranges from about 1000 g/mole to 2500 g/mole.

In some embodiments, a hardcoat layer described herein can further include nanoparticles to improve barrier performance. The nanoparticles can be hosted by a matrix polymeric material or a binder of the hardcoat layer, e.g., being embedded within the crosslinkable polymeric material thereof. In some embodiments, the nanoparticles may be a mixture of nanoparticles including, for example, from about 10 wt % to 50 wt % of a first group of nanoparticles having an average particle diameter in a range from 2 nm to 200 nm, and from about 50 wt % to about 90 wt % of a second group of nanoparticles having an average particle diameter in a range from 60 nm to 400 nm. In some embodiments, the ratio of average particle diameters of the first group of nanoparticles and the second group of nanoparticles is in a range from 1:2 to 1:200.

In some embodiments, the nanoparticles can include inorganic nanoparticles. Examples of the inorganic nanoparticles include SiO₂, ZrO₂, or Sb doped SnO₂ nanoparticles, mixtures thereof, etc. Exemplary nanoparticles include SiO₂, ZrO₂, or Sb doped SnO₂ nanoparticles, and SiO₂ nanoparticles are commercially available, for example, from Nissan Chemical Industries, Ltd., Tokyo, Japan; C. I. Kasei Company, Limited, Tokyo, Japan; and Nalco Company, Naperville, Ill. ZrO₂, nanoparticles are commercially available, for example, from Nissan Chemical Industries. Sb doped SnO nanoparticles are commercially available, for example, from Advanced Nanoproducts, Sejong-si, South Korea.

The nanoparticles can consist essentially of or consist of a single oxide such as silica, or can comprise a combination of oxides, or a core of an oxide of one type (or a core of a material other than a metal oxide) on which is deposited an oxide of another type. The nanoparticles are often provided in the form of a sol containing a colloidal dispersion of inorganic oxide particles in liquid media. The sol can be prepared using a variety of techniques and in a variety of forms including hydrosols (where water serves as the liquid medium), organosols (where organic liquids so serve), and mixed sols (where the liquid medium contains both water and an organic liquid).

In some embodiments, nanoparticles can be modified, for example, by a surface treatment agent. A surface treatment agent may have a first end that will attach to the particle surface (covalently, ionically, or through strong physisorption) and a second end that imparts compatibility of the particle with the resin and/or reacts with resin during curing. Examples of surface treatment agents include alcohols, amines, carboxylic acids, sulfonic acids, phosphonic acids, silanes and titanates. In some embodiments, the treatment agent may be determined, in part, by the chemical nature of the metal oxide surface. In some embodiments, silanes are preferred for silica and other for siliceous fillers. In some embodiments, silanes and carboxylic acids are preferred for metal oxides such as zirconia.

In some embodiments, the hardcoat layer can have a thickness, for example, no less than about 200 nm, no less than about 500 nm, no less than about one micron, no less than about 2 microns, or no less than about 3 microns. In some embodiments, the hardcoat layer may have a thickness, for example, no more than about 30 microns, no more than about 20 microns, no more than about 10 microns, no more than about 5 microns, or no more than about 3 microns.

In some embodiments, the hardcoat layer can be formed by providing a coating composition on a major surface of a substrate. The coating composition can be applied using conventional coating methods such as roll coating (e.g., gravure roll coating, or die coating), spray coating (e.g., electrostatic spray coating) or die coating, then crosslinked using, for example, ultraviolet (UV) radiation or thermal curing. A hardcoat layer coating solution can be formed, for example, by mixing crosslinkable polymeric materials and nanoparticles dissolved in solvents with additives such as, for example, photoinitiator or catalysts. In some embodiments, the hardcoat layer can be formed by applying a layer of one or more monomers or oligomers and crosslinking the layer to form the polymer in situ, for example, by evaporation and vapor deposition of one or more crosslinkable monomers cured by heat or radiation, for example, using an electron beam apparatus, UV light source, electrical discharge apparatus or other suitable device. It is to be understood that in some embodiments, the hardcoat layer may be formed by any suitable processes other than a liquid coating process such as, for example, organic vapor deposition processes.

In some embodiments, the composition of a hardcoat layer can include (a) (meth)acrylic oligomer and/or monomer binder in a range from 5 wt % to 60 wt %, (b) a mixture of nanoparticles in a range from 40 wt % to 90 wt % where 10 wt % to 50 wt % of nanoparticles (NP-1) having 2 nm to 200 nm of particle size, and 50 to 90 wt % of the nanoparticles (NP-2) having 60 nm to 400 nm of particle size, and the ratio of the particle size of NP-1 and the one of NP-2 is in a range from 1:2 to 1:200; and (c) one or more silicon (meth)acrylate (e.g., PDMS acrylate) additives in a range from 0.001 to 15 wt %.

In some embodiments, the hardcoat layer can be made by a method including coating a mixture onto a first major surface of a substrate. The mixture can include at least one of acrylic, (meth)acrylic oligomer, or monomer binder in a range from 5 weight % to 60 weight %. The binder may further include one or more silicon (meth)acrylate (e.g., PDMS acrylate) additives. The mixture further include nanoparticles in a range from 40 to 95 weight %, based on the total weight of the mixture. The nanoparticles may have an average particle diameter in a range from 2 nm to 100 nm. The at least one of acrylic, (meth)acrylic oligomer, or monomer binder can be cured by heat or radiation to form the hardcoat layer.

In some embodiments, the formed hardcoat layer on the substrate may have a thickness less than 30 microns (in some embodiments, less than 10 microns, or even less than 3 microns).

While not wanting to be bound by theory, it is believed that the one or more silicon (meth)acrylate (e.g., PDMS acrylate) additives in a hardcoat layer may migrate to the exposed surface of the hardcoat layer during solvent drying or curing. The presence of silicone (meth)acrylate (e.g., PDMS acrylate) at the surface might provide the advantage of improved durability and moisture barrier performances. For example, the silicon (meth)acrylate may improve adhesion of the barrier layer to the hardcoat layer. Also, the silicone (meth)acrylate may act as an etch mask, preventing possible damage during the following process of forming the barrier layer (e.g., plasma induced damage, etching and the consequential roughening of the underlying hard coat layer).

A barrier layer described herein such as the barrier layer 124 of FIG. 1 can be formed from a variety of materials. In some embodiments, the barrier layer may include a random covalent network containing one or more of carbon and silicon, and one or more of oxygen, nitrogen, hydrogen and fluorine. The barrier layer may further include one or more metal elements such as, for example, aluminum, zinc, zirconium, titanium, hafnium, etc. In some embodiments, the barrier layer may include one or more of metals, metal, oxides, metal nitrides, metal carbides, metal oxynitrides, metal oxycarbide, metal oxyborides, and combinations thereof. Exemplary metal oxides include silicon oxides such as silica, aluminum oxides such as alumina, titanium oxides such as titania, indium oxides, tin oxides, indium tin oxide (ITO), tantalum oxide, zirconium oxide, hafnium oxide, niobium oxide, and combinations thereof. Other exemplary materials include boron carbide, tungsten carbide, silicon carbide, aluminum nitride, silicon nitride, boron nitride, aluminum oxynitride, silicon oxynitride, boron oxynitride, zirconium oxyboride, titanium oxyboride, silicon aluminate, and combinations thereof.

In some embodiments, the barrier layer may include a diamond-like glass (DLG) film. Diamond-like glass (DLG) is an amorphous carbon system including a substantial quantity of silicon and oxygen that exhibits diamond-like properties. In these films, on a hydrogen-free basis, there is at least 30% carbon, a substantial amount of silicon (typically at least 25%) and no more than 45% oxygen. The unique combination of a fairly high amount of silicon with a significant amount of oxygen and a substantial amount of carbon makes these films highly transparent and flexible (unlike glass). Exemplary DLG materials are described in WO 2007/015779 (Padiyath and David), which is incorporated herein by reference.

In creating a diamond-like glass film, various additional components can be incorporated into the basic carbon or carbon and hydrogen composition. These additional components can be used to alter and enhance the properties that the diamond-like glass film imparts to the substrate. For example, it may be desirable to further enhance the barrier and surface properties.

The additional components may include one or more of hydrogen (if not already incorporated), nitrogen, fluorine, sulfur, titanium, or copper. Other additional components may also be of benefit. The addition of hydrogen promotes the formation of tetrahedral bonds. The addition of fluorine is particularly useful in enhancing barrier and surface properties of the diamond-like glass film. The addition of nitrogen may be used to enhance resistance to oxidation and to increase electrical conductivity. The addition of sulfur can enhance adhesion. The addition of titanium tends to enhance adhesion as well as diffusion and barrier properties.

These diamond-like materials may be considered as a form of plasma polymers, which can be deposited on the assembly using, for example, a vapor source. Use term “plasma polymer” is applied to a class of materials synthesized from a plasma by using precursor monomers in the gas phase at low temperatures. Precursor molecules are broken down by energetic electrons present in the plasma to form free radical species. These free radical species react at the substrate surface and lead to polymeric thin film growth. Due to the non-specificity of the reaction processes in both the gas phase and the substrate, the resulting polymer films are highly cross-linked and amorphous in nature. This class of materials has been researched and summarized in publications such as the following: H. Yasuda, “Plasma Polymerization, ”Academic Press Inc., New York (1985); R.d'Agostino (Ed), “Plasma Deposition, Treatment & Etching of Polymers,” Academic Press, New York (1990); and H. Biederman and Y. Osada, “Plasma Polymerization Processes,” Elsever, New York.

Typically, these polymers have an organic nature to them due to the presence of hydrocarbon and carbonaceous functional groups such as CH₃, CH₂, CH, Si—C, Si—CH₃, Al—C, Si—O—CH₃, etc. The presence of those functional groups may be ascertained by analytical techniques such as IR, nuclear magnetic resonance (NMR) and secondary ion mass (SIMS) spectroscopies. The carbon content in the film may be quantified by electron spectroscopy for chemical analysis (ESCA).

Not all plasma deposition processes lead to plasma polymers. Inorganic thin films are frequently deposited by PECVD at elevated substrate temperatures to produce thin inorganic films such as amorphous silicon, silicon oxide, silicon nitride, aluminum nitride, etc. Lower temperature processes may be used with inorganic precursors such as silane (SiH₄) and ammonia (NH₃). In some cases, the organic component present in the precursors is removed in the plasma by feeding the precursor mixture with an excess flow of oxygen. Silicon rich films are produced frequently from tetramethyldisiloxane (TMDSO)-oxygen mixtures where the oxygen flow rate is ten times that of the TMDSO flow. Films produced in these cases have an oxygen to silicon ratio of about 2, which is near that of silicon dioxide.

The plasma polymer layer in some embodiments of the present disclosure is differentiated from other inorganic plasma deposited thin films by the oxygen to silicon ratio in the films and by the amount of carbon present in the films. When a surface analytic technique such as ESCA is used for the analysis, the elemental atomic composition of the film may be obtained on a hydrogen-free basis. Plasma polymer films in some embodiments of the present disclosure are substantially sub-stoichiometric in their inorganic component and substantially carbon-rich, depicting their organic nature. In films containing silicon for example, the oxygen to silicon ratio is preferably below 1.8 (silicon dioxide has a ratio of 2.0), and most preferably below 1.5 as in the case of DLG, and the carbon content is at least about 10%. Preferably, the carbon content is at least about 20% and most preferably at least about 25%. Furthermore, the organic siloxane structure of the films may be directed by IR spectra of the film with the presence of Si—CH₃ groups at 1250 cm⁻¹ and 800 cm⁻¹, by secondly ion mass spectroscopy (SIMS).

One advantage of DLG coatings or films is their resistance to cracking in comparison to other films. DLG coatings are inherently resistant to etching either under applied stress or inherent stresses arising from manufacture of the film. The properties of exemplary DLG coatings are described in U.S. Pat. No. 8,034,452 (Padiyath and David) which is incorporated by reference herein.

In some embodiments, the barrier layer may have a thickness in the range, for example, from several nanometers to several microns (e.g., 5 nm to 5 microns).

In some embodiments, the barrier layer can be formed by a plasma process, e.g., a DLG layer formed by an ion-enhanced plasma deposition process. For the deposition of a DLG film, an organosilicon precursor vapor such as hexamethyldisiloxane (HMDSO) is mixed with oxygen gas, and plasma is generated by using radio frequency (RF), mid-frequency (MF), or microwave (MW) power at a pressure of 0.001 to 0.100 Torr. The precursor vapor, and oxygen gas are dissociated in the plasma, and react at the substrate surface to deposit the thin film, while undergoing intense ion-bombardment. Ion-bombardment is a critical aspect of the deposition process, which densifies the depositing thin film, and is achieved by a negative DC self-bias obtained on the smaller powered electrode. The pressure is maintained below 100 mTorr, preferably below 50 mTorr to minimize gas phase nucleation, and to maximize the ion bombardment. It is to be understood that a barrier layer can be formed using any suitable techniques other than a plasma process.

FIG. 3 is a schematic view of roll to roll plasma chemical vapor deposition equipment for preparing a barrier layer, according to one embodiment. In the depicted embodiment, an exemplary roll to roll (R2R) plasma deposition system 500 was used for deposition of an amorphous diamond like coatings (e.g., DLG) on the roll 504 to roll 505 polymer films 506. The system 500 includes an aluminum vacuum chamber 501 that contains two roll shape electrodes 502, 503 with chamber walls acting as the counter-electrode. Because of larger surface area of the counter electrode, the system may be considered to be asymmetric, resulting in large sheath potential at the powered electrode on which the substrate film to be coated are wrapped around. The chamber 501 is pumped by pumping system, which may include dual turbo-molecular pumps backed by a mechanical pump. Process gases 508 and 509 are metered through mass flow controllers and blended in a manifold before they are introduced into the chamber 501. The process gases, oxygen and HMDSO are stored remotely in gas cabinets and piped to the mass flow controller. The typical base pressure in the chamber is below 1×10⁻² Torr based on the size and type of the pumping system. The plasma is powered by 13.56 MHz-10500 W radio frequency power supply (MKS Spectrum, Model B-10513) through an impedance matching network (MKS, Model: MWM-100). A substrate (e.g., a polyester film from Toray Lumirror U32, 52 microns) was coated by a hardcoat layer (e.g., highly-filled nanoparticle hardcoat containing PDMS acrylate). The hard coated polyester film roll was placed in the plasma deposition chamber roll to roll coater described above and shown in FIG. 3. The roll to roll plasma deposition system 500 can be used for fabrication of a barrier layer on a base nanoparticle filled hardcoat such as the hardcoat layer 122 of FIG. 1. The base nanoparticle filled hard coated substrates can be treated by the roll to roll plasma chemical vapor deposition system where the mixed gas of HMDSO and oxygen can be used as starting materials for forming a barrier layer on the base nanoparticle filled hardcoat layer. Table 1 below illustrates exemplary conditions of ion enhanced plasma chemical vapor deposition utilizing silane sources.

TABLE 1
Condition of plasma chemical vapor deposition.

| | | P-1 | P-2 | P-3 | P-4 | P-5 | P-6 |
|---|---|---|---|---|---|---|---|
| Pressure base [mTorr] | | 14.1 | 14.0 | 14.4 | 16.4 | 15.6 | 21.1 |
| Gas A (HMDSO) | Target | 70 | 70 | 100 | 100 | 100 | 100 |
| [sccm] | Set | 80 | 80 | 110 | 100 | 100 | 100 |
| | Act | 76 | 75 | 93 | 91 | 92 | 88 |
| Gas B (O₂) | Target | 100 | 100 | 110 | 110 | 110 | 110 |
| [sccm] | Set | 100 | 100 | 110 | 110 | 110 | 110 |
| | Act | 96 | 99 | 109 | 108 | 108 | 108 |
| Ratio (O2/HMDSO) | | 1.303 | 1.302 | 1.172 | 1.187 | 1.174 | 1.227 |
| Web Information | Treatment time [sec] | 300 | 180 | 200 | 250 | 110 | 150 |
| | Line Speed [ft/min] | 2 | 2 | 3 | 3 | 3 | 3 |
| RF Condition | Target [W] | 6000 | 6000 | 6000 | 6000 | 6000 | 6000 |
| | Set [W] | 6000 | 6000 | 6000 | 6000 | 6000 | 6000 |
| | Act(fwd)[W] | 6003 | 6001 | 6003 | 6004 | 6004 | 6004 |
| | Refraction[W] | 11 | 9 | 13 | 11 | 11 | 8 |

| | | | | | | |
|---|---|---|---|---|---|---|
| Prfon [mTorr] | 58.7 | 61.6 | 84.0 | 68.0 | 69.1 | 74.3 |
| Dose [ [symbol] /cm2] | 44 | 44 | 29 | 29 | 29 | 29 |
| Pwr density [W/cm²] | 0.23 | 0.23 | 0.23 | 0.23 | 0.23 | 0.23 |

[symbol]

indicates data missing or illegible when filed

FIG. 2 is a schematic cross-sectional view of a device 200 making use of the barrier stack 120 of FIG. 1, according to one embodiment. The device 200 may be a LCD device that can be laminated to a touch sensor. In the depicted embodiment, the device 200 includes a polarizer 230 that is sandwiched, via an adhesive layer 220 (e.g., an optically clear adhesive or OCA, a barrier adhesive) between a glass substrate (not shown) of the LCD device and a cover panel 210. Exemplary OCAs are described in WO 2013/025330 (Rotto et at.) which is incorporated herein by reference. Exemplary barrier adhesives are described in U.S. Pat. No. 8,663,407 (Joly et al.) which is incorporated herein by reference. The cover panel 210 can be made, for example, glass, polycarbonate, polymethylmethacrylate. The barrier stack 120 disposed between the cover panel 210 and the adhesive layer 220, and configured to prevent diffusion of moisture or oxygen from the cover panel 210 to the optically clear adhesive layer 220. In the absence of the barrier stack 120, bubbles may be generated in the optically clear adhesive layer 220 due to gas diffusion from the cover panel 210.

Multilayer barrier films (e.g., a barrier stack such as 120 with or without a substrate such as 110) described herein can be used for various devices including, for example, displays (e.g., including barrier films and quantum dot layer are described in WO 2014/113562 to Nelson, et al. which is incorporated herein by reference, LCDs, OLEDs, etc.), solar cells, and other devices that may require higher moisture barrier and anti-scratching performance. The multilayer barrier films can have a water vapor transmission rate (WVTR) no more than about 1 g/m²/day at 38° C. and 100% relative humidity, less than about 0.5 g/m²/day at 38° C. and 100% relative humidity; in some embodiments, less than about 0.05 g/m²/day at 38° C. and 100% relative humidity. In some embodiments, a barrier stack such as 120 may have a WVTR of less than about 1, 0.5, 0.05, 0.005, 0.0005, or 0.0005 g/m²/day at 50° C. and 100% relative humidity or even less than about 1, 0.5, 0.005, 0.0005 g/m²/day at 85° C. and 100% relative humidity. In some embodiments, the multilayer barrier films may have an oxygen transmission rate (OTR) of less than about 0.005 cm³/m²/day at 23° C. and 90% relative humidity; and in some embodiments, less than about 0.00005 cm³/m²/day at 23° C. and 90% relative humidity. In some embodiments, multilayer barrier films described herein can exhibit superior anti-scratching properties and can be resistant to scratching by a steel wool. In some embodiments, the multilayer barrier film may have a change of haze values ( [symbol] haze) in a range from −1.0 to 1.0 after steelwool abrasion resistance testing. A “haze test” is comparing the difference in haze values before and after the subjecting the samples to steel wool abrasion resistance testing, which will be discussed further below.

Exemplary embodiments of the present disclosure may take on various modifications and alterations without departing from the spirit and scope of the present disclosure. Accordingly, it is to be understood that the embodiments of the present disclosure are not to be limited to the following described exemplary embodiments, but is to be controlled by the limitations set forth in the claims and any equivalents thereof.

Various exemplary embodiments of the disclosure will now be described with particular reference to the Drawings. Exemplary embodiments of the present disclosure may take on various modifications and alterations without departing from the sprit and scope of the disclosure. Accordingly, it is to be understood that the embodiments of the present disclosure are not to be limited to the following described exemplary embodiments, but are to be controlled by the limitations set forth in the claims and any equivalents thereof.

### LISTING OF EXEMPLARY EMBODIMENTS

Any one of embodiments 1-22 and 23-24 can be combined.

Embodiment 1 is a multilayer barrier film, comprising:
a hardcoat layer comprising nanoparticles hosted by a binder, the binder comprising one or more silicone (meth)acrylate additives; and
a barrier layer directly disposed on a major surface of the hardcoat layer.

Embodiment 2 is the multilayer barrier film of embodiments 1 wherein the one or more silicone (meth)acrylate additives include polydimethylsiloxane (PDMS) acrylate, and the hardcoat layer comprises from about 0.01 wt % to about 10 wt % of the polydimethylsiloxane (PDMS) acrylate based on the total weight of the hardcoat layer.

Embodiment 3 is the multilayer barrier film of embodiment 1 or 2, wherein the binder of the hardcoat layer further comprises cured acrylate formed by curing at least one of acrylic, (meth)acrylic oligomer, or monomer binder.

Embodiment 4 is the multilayer barrier film of any one of embodiments 1-3, wherein the hardcoat layer comprises from about 15 wt % to about 70 wt % of the binder and from about 30 wt % to about 85 wt % of the nanoparticles based on the total weight of the hardcoat layer.

Embodiment 5 is the multilayer barrier film of any one of embodiments 1-4, wherein the nanoparticles comprises from about 1.0 wt % to 50 wt % of a first group of nanoparticles having an average particle diameter in a range from 2 nm to 200 nm, and from about 50 wt % to about 90 wt % of a second group of nanoparticles having an average particle diameter in a range from 60 nm to 400 nm.

Embodiment 6 is the multilayer barrier film of embodiment 5, wherein the ratio of average particle diameters of the first group of nanoparticles and the second group of nanoparticles is in a range from 1:2 to 1:200.

Embodiment 7 is the multilayer barrier film of any one of embodiments 1-6, wherein the nanoparticles include modified nanoparticles.

Embodiment 8 is the multilayer barrier film of any one of embodiments wherein the nanoparticles include one or more of SiO₂, ZrO₂, or Sb doped, SnO₂ nanoparticles.

Embodiment 9 is the multilayer barrier film of any one of embodiments 1-8, wherein the hardcoat layer has a thickness in a range from about 0.5 micron to about 30 micron.

Embodiment 10 is the multilayer barrier film of embodiment 9, wherein the hardcoat layer has a thickness less than about 10 micron.

Embodiment 11 is the multilayer barrier film of any one of embodiments 1-10, wherein the barrier layer comprises a random covalent network containing silicon and one or more of carbon, oxygen, nitrogen, hydrogen and fluorine.

Embodiment 12 is the multilayer barrier film of any one of embodiments 1-11, wherein the barrier layer further comprises one or more of metal elements including aluminum, zinc, titanium, indium, and zirconium.

Embodiment 13 is the multilayer barrier film of any one of embodiments 1-12, wherein the barrier layer is a layer of diamond-like glass (DLG) material.

Embodiment 14 is the multilayer barrier film of any one of embodiments 1-13, wherein the barrier layer has a thickness from about 5 nm to about 3 microns.

Embodiment 15 is the multilayer barrier film of any one of embodiments 1-14, further comprising a substrate, and the hardcoat layer being disposed between the substrate and the barrier layer.

Embodiment 16 is the multilayer barrier film of embodiment 13, wherein the substrate comprises poly ethylene terephthalate (PET), polycarbonate (PC), polyethylene naphthalate (PEN), poly(methyl methacrylate) (PMMA), triacetylecellulose (TAC), or the combination thereof.

Embodiment 17 is the multilayer barrier film of embodiment 15 or 16, wherein the substrate is a polarizer.

Embodiment 18 is the multilayer barrier film of any one of the proceeding embodiments, having a water vapor transmission rate (WVTR) no more than about 1 g/m²/day at 40° C. and 90% RH.

Embodiment 19 is the multilayer barrier film of any one of the proceeding embodiments, having a change of haze values in a range from −1.0 to 1.0 after a steelwool abrasion resistance test.

Embodiment 20 is a device comprising the multilayer barrier film of any one of the proceeding embodiments.

Embodiment 21 is the device of embodiment 20, further comprising a cover panel and an optically clear adhesive layer, the multilayer barrier film is disposed between the cover panel and the optically clear adhesive layer, and configured to prevent diffusion of moisture or oxygen from the cover panel to the optically clear adhesive layer.

Embodiment 22 is the device of embodiment 20 or 21, which is a liquid crystal display (LCD).

Embodiment 23 is a method of making a multilayer barrier film, the method comprising:
providing a mixture comprising nanoparticles and one or more curable binder materials;
curing the binder materials to provide a hardcoat layer, the hardcoat layer comprising the nanoparticles hosted by the binder, the binder further comprising one or more silicone (meth)acrylate additives; and
providing a barrier layer directly disposed on the hardcoat layer.

Embodiment 24 is the method of embodiment 23, wherein the barrier layer is formed by ion-enhanced plasma chemical vapor deposition.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Summary of Materials

Unless otherwise noted, all parts, percentages, ratios, etc. in the Examples and the rest of the specification are by weight. Table 2 provides abbreviations and a source for all materials used in the Examples below:

TABLE 2

| Abbreviation | Description | Source |
|---|---|---|
| “A-174” | 3-methacryloxypropyl- | obtained from Alfa Aesar, Ward Hill, |
| | trimethoxysilane | MA, under trade designation “SILQUEST |
| | | A-174” |
| “PROSTAB” | 4-hydroxy-2,2,6,6- | obtained from Aldrich Chemical |
| | tetramethylpiperidine 1-oxyl | Company, Milwaukee, WI, under trade |
| | (5 wt. %) | designation “PROSTAB” |
| “NALCO 2327” | 20 nm diameter SiO₂ sol | obtained from Nalco Company, |
| | | Naperville, IL, under trade designation |
| | | “NALCO 2327” |
| “NALCO 2329” | 75 nm diameter SiO₂ sol | obtained from Nalco Company under |
| | | trade designation “NALCO 2329” |
| “EBECRYL 8701” | trifunctional aliphatic | obtained from Daicel-Allnex, Ltd. under |
| | urethane acrylate | trade designation “EBECRYL 8701” |
| “SR238NS” | 1,6-hexanediol diacrylate | obtained from Arkema Group, Clear Lake, |
| | | under trade designation “SARTOMER |
| | | SR238NS” |
| “Tegorad 2500” | Acrylated poly dimethyl | obtained from EVONIK INDUSTRIES, |
| | siloxane (PDMS) | Essen, Germany under trade designation |
| | | “Tegorad 2500” |
| “ESACURE ONE” | difunctional alpha | obtained from Lamberti, Galarate, Italy, |
| | hydroxyketone | under trade designation “ESACURE |
| | | ONE” |
| 1-methoxy-2- | solvent | obtained from Aldrich Chemical |
| propanol | | Company, Milwaukee, WI |
| Methylethyl | solvent | obtained from Aldrich Chemical |
| Ketone | | Company, Milwaukee, WI |
| “Panlite 400 μm” | Polycarbonate film | obtained from TEIJIN Limited, Osaka, |
| | | Japan, under trade designation “Panlite |
| | | 400 μm” |
| “LUMIRROR U32 | Poly ethylene terephthalate | obtained from TORAY INDUSTORIES |
| 50 μm” | film | INC, Tokyo, Japan, under trade |
| | | designation “LUMIRROR U32 50 μM” |

### Sample Preparation

### Preparation of Surface Modified Silica Sol (Sol-1)

5.95 grains of 3-methacryloxypropyl-trimethoxysilane (“A-174”) and 0.5 gram of 4-hydroxy-2,2,6,6-tetramethylpiperidine 1-oxyl (5 wt. %; “PROSTAB”) was added to a mixture of 400 grams of 75 nm diameter SiO₂ sol (“NALCO 2329”) and 450 grams of 1-methoxy-2-propanol in a glass jar with stirring at room temperature for 10 minutes. The jar was sealed and placed in an oven at 80° C. for 16 hours. The water was removed from the resultant solution with a rotary evaporator at 60° C. until the solid content of the solution was close to 45 wt. %. 200 grams of 1-methoxy-2-propanol was charged into the resultant solution, and then remaining water was removed by using the rotary evaporator at 60° C.. This latter step was repeated for a second time to further remove water from the solution. The concentration of total SiO₂ nanoparticles was adjusted to 45.0 wt. % by adding 1-methoxy-2-propanol to result in the SiO₂ sol containing surface modified SiO₂ nanoparticles with an average size of 75 nm.

### Preparation of Surface Modified Silica Sol (Sol-2)

25.25 grams of A-174 and 0.5 gram of 4-hydroxy-2,2,6,6-tetramethylpiperidine 1-oxyl (5 wt. %; “PROSTAB”) was added to a mixture of 400 grams of 20 nm diameter SiO₂ sol (“NALCO 2327”) and 450 grams of 1-methoxy-2-propanol in a glass jar with stirring at room temperature for 10 minutes. The jar was sealed and placed in an oven at 80° for 16 hours. The water was removed from the resultant solution with a rotary evaporator at 60° C. until the solid content of the solution was close to 45 wt. %, 200 grams of 1-methoxy-2-propanol was charged into the resultant solution, and then remaining water was removed by using the rotary evaporator at 60° C. This latter step was repeated for a second time to further remove water from the solution. The concentration of total SiO₂ nanoparticles was then adjusted to 45.0 wt. % by adding 1-methoxy-2-propanol to result in a SiO₂ sol containing surface modified SiO₂ nanoparticles with an average size of 20 nm.

### Preparation of Base Nanoparticle Filled Hardcoat Precursor (HC-1)

433 grams of Sol-1, 2.33 grams of Sol-2, 0.8 grams of trifunctional aliphatic urethane acrylate (“EBECRYL 8701”) and 0.2 gram of 1,6-hexanediol diacrylate (“SR238NS”) were mixed. 0.12 grams of difunctional alpha hydroxyketone (“ESACURE ONE”) as the photoinitiator, and 1.8 grams of methyl ethyl ketone were then added to the mixture. The mixture was adjusted to 40.71 wt % in solids by adding 0.53 grams of 1-methoxy-2-propanol, and the hardcoat precursor HC-1 was provided.

### Preparation of Base Nanoparticle Filled Hardcoat Precursor (HC-2)

4.33 grams of Sol-1, 2.33 grams of Sol-2, 0.8 grams of trifunctional aliphatic urethane acrylate (“EBECRYL 8701”) and 0.2 gram of 1,6-hexanediol diacrylate (“SR238NS”) were mixed. 0.004 gram of Acrylated poly dimethyl siloxane (PDMS) was added as an interface adhesion promoter. 0.12 grams of difunctional alpha hydroxy ketone (“ESACURE ONE”) as the photoinitiator and 1.8 grams of methyl ethyl ketone were then added to the mixture. The mixture was adjusted to 40.73 wt % in solids by adding 0.53 grams of 1-methoxy-2-propanol, and the hardcoat precursor HC-2 was provided.

### Preparation of Base Nanoparticle Filled Hardcoat Precursor (HC-3, 4, 5, 6)

HC-3, 4, 5 and 6 was prepared following the same procedure for HC-2. Details of formulation are described in Table 3.

TABLE 3
Formulation of base nanoparticle filled hardcoat for poly ethylene terephthalate

| | HC-1 | HC-2 | HC-3 | HC-4 | HC-5 | HC-6 | HC-7 |
|---|---|---|---|---|---|---|---|
| 75 nm SiO2 | 4.33 | 4.33 | 4.33 | 4.33 | 4.33 | 4.33 | 1300.00 |
| functionalized by | | | | | | | |
| A174 (Sol-1) | | | | | | | |
| 20 nm SiO2 | 2.33 | 2.33 | 2.33 | 2.33 | 2.33 | 2.33 | 700.00 |
| functionalized by | | | | | | | |
| A174 (Sol-2) | | | | | | | |
| EBECRYL 8701 | 0.80 | 0.80 | 0.80 | 0.80 | 0.80 | 0.80 | 240.00 |
| SR238NS | 0.20 | 0.20 | 0.20 | 0.20 | 0.20 | 0.20 | 60.00 |
| Tegorad2500 | 0.000 | 0.004 | 0.008 | 0.016 | 0.040 | 0.080 | 2.400 |
| Esacure One | 0.12 | 0.12 | 0.12 | 0.12 | 0.12 | 0.12 | 36.00 |
| Methyl Ethyl Ketone | 1.80 | 1.80 | 1.80 | 1.80 | 1.80 | 1.80 | 557.25 |
| (MEK) | | | | | | | |
| 1-methoxy-2-propanol | 0.53 | 0.53 | 0.53 | 0.53 | 0.53 | 0.53 | 200.25 |
| Solid wt % | 40.71% | 40.73% | 40.76% | 40.81% | 40.94% | 41.18% | 40.00% |

### Preparation of Base Nanoparticle Filled Hardcoat Precursor (HC-7)

HC-7 was used for roll sample preparation. 1300 grams of Sol-1, 700 grams of Sol-2, 240 grams of trifunctional aliphatic urethane acrylate (“EBECRYL 8701”) and 60 gram of 1,6-hexanediol diacrylate (“SR238NS”) were mixed. 2.4 gram of Acrylated poly dimethyl siloxane (PDMS) was added as an interface adhesion promoter. 36 grams of difunctional alpha hydroxyketone (“ESACURE ONE”) as the photoinitiator and 557.25 grams of methyl ethyl ketone were then added to the mixture. The mixture was adjusted to 40.0 wt. % in solids by adding 200.25grams of 1-methoxy-2-propanol, and the hardcoat precursor HC-7 was provided.

### Preparation of Base Nanoparticle Filled Hardcoat Precursor (HC-8, 9, 10)

HC-8, 9, 10 was prepared for polycarbonate substrate. Details of formulation are described in Table 4.

TABLE 4
Formulation of base nanoparticle filled hardcoat for polycarbonate
substrate

| | HC-8 | HC-9 | HC-10 |
|---|---|---|---|
| 75 nm SiO2 functionalized by A14 (Sol-1) | 4.33 | 4.33 | 4.33 |
| 20 nm SiO2 functionalized by A14 (Sol-2) | 2.33 | 2.33 | 2.33 |
| EBECRYL 8701 | 0.80 | 0.80 | 0.80 |
| SR238NS | 0.20 | 0.20 | 0.20 |
| Tegorad2500 | 0.0016 | 0.004 | 0.008 |
| Esacure One | 0.12 | 0.12 | 0.12 |
| 1-methoxy-2-propanol | 2.33 | 2.33 | 2.33 |
| Solid wt % | 40.73% | 40.75% | 40.77% |

### Coating & Curing of Base Nanoparticle Filled Hardcoat Layer

### Fabrication of PET Sheet Sample

PET film with thickness of 50 μm, obtained from TORAY INDUSTORYS INC “Lumirror U32” was fixed on glass table with level adjustment, and then the precursor solution was coated on the substrate by Mayer Rod #8. After drying for 5 min at 60° C. in the air, the coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface.

### Fabrication of PET Roll Sample

PET film with thickness of 50 μL obtained ten TORAY INDUSTORYS INC “Lumirror U32”, was used as substrate. Required coating thickness is 2.0 micron in dry. SD gravure coating method was applied by using a coater where 130line-120% w/r with 40.0 wt % solid for 2.0 micron were the coating condition. HT-40EY ROKI filter was used for in-line filtering. The three zone oven temperature was set at 87/85/88° C. (for actual 59/67/66° C. of Z1/Z2/Z3 zones) with 30/40/40 Hz oven fan inverter set number. Line speed and UV power were feed at 6 mpm and 40% output (N₂ purged (120-240 ppm O₂), Fusion 240 W/cm system, H-bulb), respectively. Web tension was 20/24/19/20 N (250 mm web) at Unwinder (UW)/Input/Oven/Winder, respectively. UW and Winder used 3 inch film roll cores.

### Fabrication of Polycarbonate Sheet Sample

Polycarbonate with thickness of 400 microns, obtained from TEIJIN Limited under trade name “Panlite” was fixed on glass table with level adjustment, and then the precursor solution was coated on the substrate by Mayer Rod # 8. After drying for 5 mm at 60° C. in the air, the coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface.

### Comparative Example 1 (CE-1)

CE-1 was prepared by using the “Lumirror U32” PET film as a substrate and then forming m nanoparticle filled hardcoat coating with thickness of 3.2 micrometer using HC-1. The nanoparticle filled hardcoat layer was formed by Mayer Rod #8 and then drying for 5 minutes at 60° C in the air. The coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface. The obtained film was treated by roll to roll plasma chemical vapor deposition equipment on the condition P-1 of Table 1 further above. The CE-1 was prepared.

### Example (Ex-01, 02, 03, 04, 05)

Ex-01, 02, 03, 04 and 05 was prepared by using the “Lumirror U32” PET film as a substrate and then forming a nanoparticle filled hardcoat coating with thickness of 3.2 micrometer using HC-2, 3, 4, 5 and 6, respectively. The nanoparticle filled hardcoat layer was formed by Mayer Rod #8 and then drying for 5 minutes at 60° C. in the air. The coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface. The obtained film was treated by roll to roll plasma chemical vapor deposition equipment on the condition P-1 of Table 1 further above. The durable barrier layer on PET film was prepared as Example 01, 02, 03, 04 and 05, respectively,

### Comparative Example 2 (CE-2)

Hardcoat precursor solution (HC-7) was coated on the substrate by SD gravure. PET film with thickness of 50 μm, obtained from TORAY INDUSTORYS INC “Lumirror U32” was used as substrate. Required coating thickness is 2.7 micron in dry. 130 line-120% w/r with 40.0 wt % solid for 2.7 micron were the coating condition. HT-40EY ROKI filter was used for in-line filtering. The three zone oven temperature was set to 87/85/88° C. (for actual 59/67/66° C. of Z1/Z2/Z3 zones) with 30/40/40 Hz oven fan inverter set number. Line speed and UV power were fixed at 6 mpm and 40% output (N₂ purged (120-240 ppm O₂). Fusion 240 W/cm system, H-bulb), respectively. Web tension was 20/24/19/20 N (for 250 mm web) at UW/Input/Oven/Winder, respectively. UW and Winder used 3 inch film roll cores. The base nanoparticle filled hardcoat was prepared as Comparative Example 2.

### Example 06 (Ex-06)

Hardcoat precursor solution (HC-7) was coated on the substrate by SD gravure. PET film with thickness of 50 μm, obtained from TORAY INDUSTORYS INC “Lumirror U32” was used as substrate. Required coating thickness is 2.0 micron in dry. 130 line-120% w/r with 40.0 wt % solid for 2.0 μm were the coating condition. HT-40EY ROKI filer was used for in-line filtering. The three zone oven temperature was set at 87/85/88° C. (for actual 59/67/66° C. of Z1/Z2/Z3 zones) with 30/40/40 Hz oven fan inverter set number. Line speed and UV power were fixed 6 mpm and 40% output (N₂ purged (120-240 ppm O₂), Fusion 240 W/cm system, H-bulb), respectively. Web tension was 20/24/19/20 M (for 250 mm web) at UW/Input/Oven/Winder, respectively. UW and Winder used 3 inch film roll core. The obtained film was treated by roll to roll plasma chemical vapor deposition equipment on the condition P-2 of Table 1 further above. The durable barrier layer on PET film was prepared as Example 06.

### Comparative Example 3 (CE-3)

Polycarbonate sheet with thickness of 400 μm obtained from TEIJIN limited under trade designation “Panlite 400 μm” was used as Comparative Example 3.

### Example 07 and Example 08 (Ex-07 and Ex-08)

Ex-07 and Ex-08 were prepared by using the “Panlite” polycarbonate sheet as a substrate and then forming a nanoparticle filled hardcoat coating with thickness of 3.2 micrometer using HC-8. The nanoparticle filled hardcoat layer was formed by Mayer Rod #8 and then drying for 5 minutes at 60° C. in the air. The coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface. The obtained film was treated by roll to roll plasma chemical vapor deposition equipment on the condition P-3 and P-4, respectively, of Table 1 further above. The durable barrier layer on polycarbonate sheet was prepared as Example 07 and 08, respectively.

### Example 9 and 10 (Ex-9 and Ex-10)

Ex-9 and Ex-10 were prepared by using the “Panlite” polycarbonate sheet as a substrate and then forming a nanoparticle filled hardcoat coating with thickness of 3.2 micrometer using HC-9. The nanoparticle filled hardcoat layer was formed by Mayer Rod #8 and then drying for 5 minutes at 60° C. in the air. The coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface. The obtained film was treated by roll to roll plasma chemical vapor deposition equipment on the condition P-5 and P-6, respectively, of Table 1 further above. The durable barrier layer on polycarbonate sheet was prepared as Example 10 and 11, respectively.

### Example 11 (Ex-11)

Ex-11 was prepared by using the “Panlite” polycarbonate sheet as a substrate and then forming a nanoparticle filled hardcoat coating with thickness of 3.2 micrometer using HC-10. The nanoparticle filled hardcoat layer was formed by Mayer Rod #8 and then drying for 5 minutes at 60° C. in the air. The coated substrate was passed 2 times into UV irradiator (H-bulb (DRS model) from Heracus Noblelight America LLC., MD) under nitrogen gas. During irradiation, 900 mJ/cm², 700 mW/cm² of ultraviolet (UV-A) was totally irradiated on the coated surface. The obtained film was treated by roll to roll plasma chemical vapor deposition equipment on the condition P-6 of Table 1 further above. The durable barrier layer on polycarbonate sheet was prepared as Example 11.

### Test Methods

### Method for Determining Optical Properties

The optical properties such as clarity, haze, and percent transmittance (TT) of the samples prepared according to the Examples and Comparative Examples were measured by using a haze meter (obtained under the trade designation “NDH5000W” from NIPPON DENSHOKU INDUSTRIES CO., LTD, Tokyo, Japan). Optical properties were determined on as prepared samples (i.e., initial optical properties) and after subjecting the samples to steel wool abrasion resistance testing. A “haze test” is comparing the difference in haze values before and after the subjecting the samples to steel wool abrasion resistance testing.

### Method for Determining Water Contact Angle

Water contact angle of the durable barrier layer was measured by sessile drop method with DROPMASTER FACE (contact angle meter obtained from Kyowa Interface Science Co., Ltd). The value of the contact angle was calculated from the average of 5 measurements.

### Method for Determining Adhesion Performance at Interface Between Durable Barrier Layer and a Substrate

Adhesion performance of the samples prepared according to the Examples and Comparative Examples was evaluated by cross cut test, according to JIS K5600 (April 1999), where 5×5 grid with 1 mm of interval (i.e., 25 one mm by one mm squares) and tape (obtained under the trade designation “NICHIBAN” from Nitto Denko CO., LTD, Osaka Japan.) was used.

### Method for Determining Steel Wool Abrasion Resistance

The scratch resistance of the samples prepared according to the Example and Comparative Examples was evaluated by the surface changes after the steel wool abrasion test using 30 mm diameter #0000 steel wool after 10 cycles at 350 gram load and at 60 cycles/min. rate. The strokes were 85 mm long. The instrument used for the test was an abrasion tester (obtained under the trade designation “IMC-157C” from Imoto Machinery Co., LTD, Kyoto Japan). After the steel wool abrasion resistance test was completed, the samples were observed for the presence of scratches and their optical properties (percent transmittance, haze, and [symbol] Haze, i.e., haze after abrasion test-initial haze) were measured again using the method described above.

Method for Determining Water Vapor Transmission Rate [mg/m²/Day]

Water vapor transmission rate of the samples prepared according to the Examples and Comparative Examples was evaluated by AQUATRAM® Model 2 produced from MOCON Inc. according to ISO 15106-3. WVTR properties under 40° C./90 RH % condition were determined on as prepared samples (i.e., initial optical properties) and after subjecting the samples to steel wool and cotton abrasion resistance testing.

### Method for Determining Bubble Generation Resistance in Optically Clear Adhesive on the Durable Barrier Layer on Polycarbonate Sheet

Bubble generation resistance in optically clear adhesive on the durable barrier layer on polycarbonate was evaluated under 95° C. for 24 h and 85° C./85 RH %, respectively. Bubble generation in OCA was evaluated after the environmental testing by visual inspection under fluorescent light.

### Sample Preparation for Evaluation of Bubble Generation Resistance

1. The silicone-treated film was removed from the OCA(CEF2807, 3M), and it was laminated to a glass substrate (70×45×0.7 mm) using rubber roller.

2. The opposite side silicone-treated film was removed from the OCA(CEF2807, 3M), and it laminated on to durable barrier layer surface on polycarbonate sheet (80×55×1 mm) using a vacuum laminator TPL-0209 MH (Takatori Corp.). The lamination condition were as follows; lamination force 1000N, lamination time 5 seconds and vacuum of 100 Pa.

3. Use #2 was sample was placed in an autoclave and treated under 0.5 MPa for 30 min at 60 degree C.

4. UV light was irradiated to the laminate through the glass of sample by using USHIO UVX-02528S1XK01 (120 W/cm). The lamp type was metal halide lamp (UVL-7000M4-N) and the total UV energy measured by UV POWER PUCK® II (EIT, Inc.) was 3000 mJ/cm² for UV-A (320-390 nm).

5. The #4 sample placed in environmental testing oven under 95° C. for 24 hours and 85° C./85% RH for 24 hours, respectively.

### Results

The resulting CE-1 to CE-3 and EX-1 to EX-11 samples were tested using methods described above.

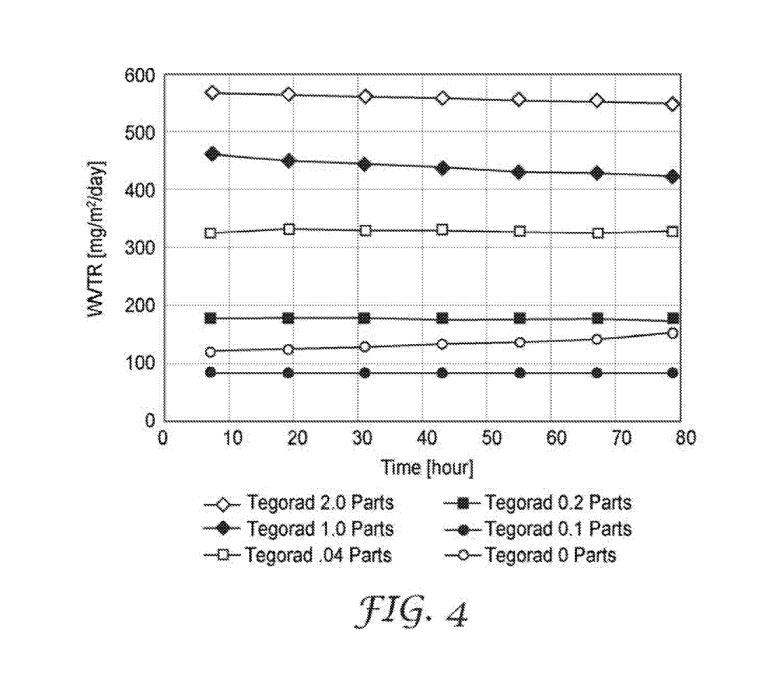

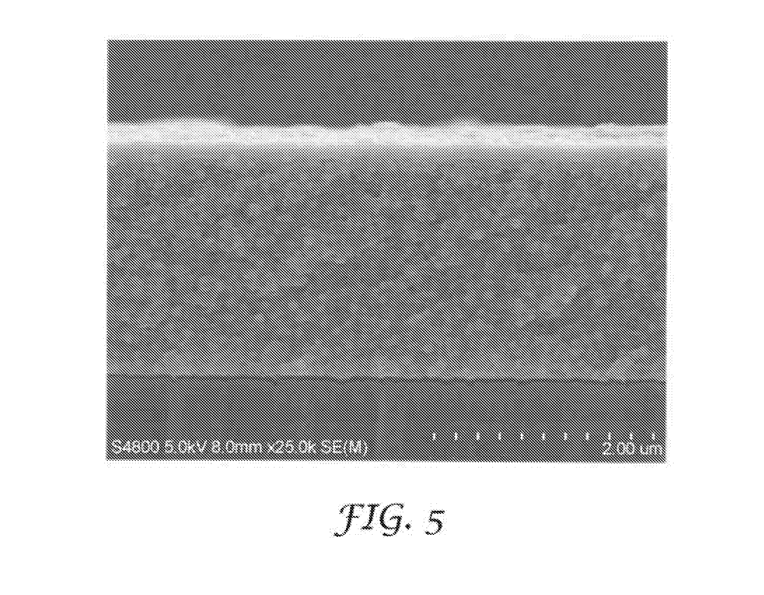

Table 5 below summarizes evaluation results of WVTR of durable barrier films on PET film with various amount of polydimethyl siloxane acrylate after 40° C./90% RH for 79 hours. Ex-1 to Ex-5 which exhibited higher barrier performance, where delamination and cracks were hardly observed on the surface after WVTR testing. And the value of WVTR increased with increasing amount of polydimethyl siloxane acrylate in base nanoparticle filled hardcoat. CE-1 also showed 155 mg/m²/day of WVTR, however cracks were observed on the surface after WVTR testing. FIG. 4 shows relationship between WVTR under 40° C. 90% RH and time with various additive amount of Tegorad (poly dimethyl siloxane acrylate). It could be noted that Ex-1 to Ex-5 maintained the WVTR performance, on the other hand, WVTR of CE-01 increased over time. This is one of the evidence that the poly dimethyl siloxane acrylate in base nanoparticle hardcoat could improve the stability of WVTR performance of barrier films.

TABLE 5
WVTR of durable barrier films with various amount of polydimethyl
siloxane acrylate after 40° C./90% RH for 79 hours

| | | Amount | | |
|---|---|---|---|---|
| | | of | Plasma | WVTR |
| | | Tegorad | Deposition | 40 C./90 RH % |
| Samples | Hardcoat | [Parts] | Condition | [mg/m2/day] |
| CE-01 | HC-1 | 0.0 | P-1 | 155 |
| Ex-01 | HC-2 | 0.1 | P-1 | 85 |
| Ex-02 | HC-3 | 0.2 | P-1 | 176 |
| Ex-03 | HC-4 | 0.4 | P-1 | 326 |
| Ex-04 | HC-5 | 1.0 | P-1 | 425 |
| Ex-05 | HC-6 | 2.0 | P-1 | 549 |

Table 6 summarizes evaluation results of durability of the barrier film by steelwool and cotton abrasion testing. Ex-06 sample showed 1.15% of haze value, 84.19% of total transmittance and 97.8° of water contact angle. Moreover the WVTR of Ex-06 was 2.077 mg/m²/day. After steelwool abrasion testing, the haze value could he maintained with [symbol] Haze less than 1%, in addition scratches and cracks were hardly observed on the surface.

TABLE 6
Durability of the barrier film by steelwool and cotton abrasion testing.

| | | Amount | | | | | | | | | | | |
|---|---|---|---|---|---|---|---|---|---|---|---|---|---|
| | | of | Plasma | | | | | | | | | | |
| | | Tegorad | Deposition | Initial Properties | | | | | After Steelwool testing | | | Steel | Cotton |
| Samples | Hardcoat | [Parts] | Condition | HZ | TT | CA | Adhesion | [symbol] | HZ | TT | [symbol] HZ | [symbol] | [symbol] |
| CE- [symbol] 2 | HC-7 | 0.20 | — | 0.95 | 92.05 | [symbol] .3 | OK | [symbol] | 3.92 | 93.11 | −0.04 | [symbol] | [symbol] |
| Ex- [symbol] 6 | HC-7 | 0.20 | P-2 | [symbol] | 84.19 | 97. [symbol] | OK | 2.077 | 1.47 | 92.87 | 0.32 | 3. [symbol] | 2.9 [symbol] |

[symbol]

indicates data missing or illegible when filed

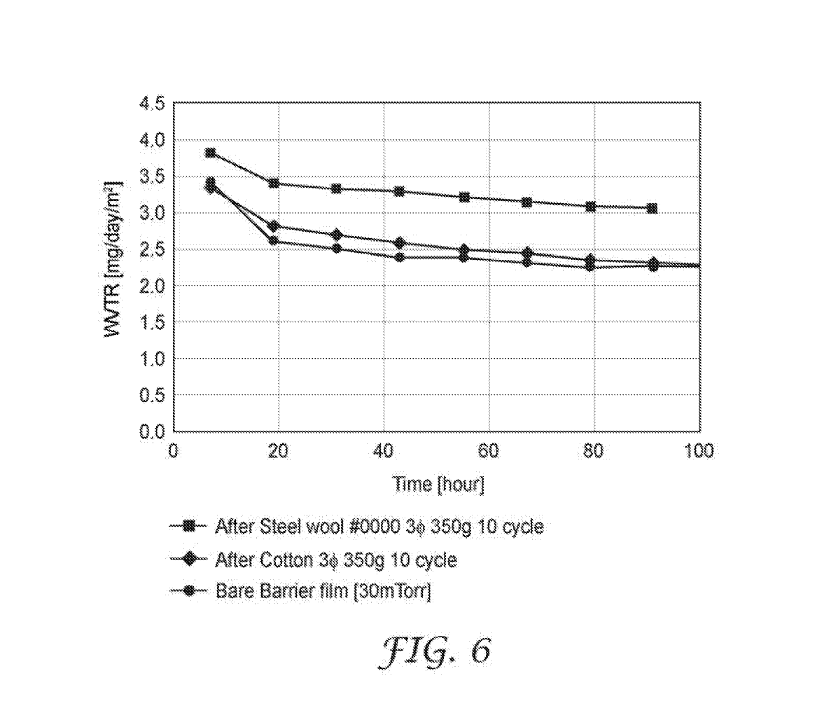

FIG. 5 shows SEM cross sectional view of Ex-06 samples. Plasma deposited layer with thickness of 140 nm was put on the base nanoparticle filled hardcoat layer, and the plasma deposited layer had a high level of uniformity and was crack-free. It is worth mentioning that Ex-06 sample showed 2.086 mg/m²/day and 3.060 mg/m²/day of WVTR even after cotton and steelwool abrasion resistance testing, respectively. WVTR slightly decreased with over time even after abrasion resting as seen in FIG. 6. In contrast, CE-02 of the base nanoparticle filled hardcoat without plasma deposition layer was hardly evaluated by AQATRAN2 equipment because of over measurement limit than 5000 mg/m²/day. From these results, it could be interpreted that the invented barrier film is a “durable” barrier film.

Table 7 below summarizes evaluation results of WVTR of durable barrier films on polycarbonate sheet. CE-03, bare polycarbonate sheet, showed over measurement limit than 5000 mg/m²/day and easily occur scratches on the surface after abrasion resistance testing. And bubbles were generated in optically clear adhesive after environmental testing under 95° C. and 85° C./85% RH owing to gas coming from polycarbonate sheet. On the contrary, all of samples of Ex-07 to Ex-11 exhibited lower [symbol] Haze (e.g., less than 1%), good adhesion performance and lower value of WVTR comparing with CE-03. Furthermore, bubbles were hardly observed by visual inspection even after environmental testing under 95° C. for 24 hours, indicating that bubble generation resistance dramatically improved by durable barrier layer using plasma chemical vapor deposition and nanoparticle filled hardcoat. Ex-9, Ex-10 and Ex-11 samples could prevent bubble generation even after environmental testing under 85° C./85%.

TABLE 7
Evaluation result of the barrier layer on polycarbonate sheet

| | | Amount | | | | | | | | | | | | |
|---|---|---|---|---|---|---|---|---|---|---|---|---|---|---|
| | | of | Plasma CVD | | | | | | | | | | | |
| | | Tegorad | | Deposition | Initial Properties | | | | | After Steelwool testing | | | [symbol] | |
| Samples | Hardcoat | [Parts] | Condition | Time [Sec] | HZ | TT | CA | Adhesion | [symbol] | HZ | TT | [symbol] HZ | [symbol] | [symbol] |
| CE-03 | — | — | — | — | 0.34 | 90.25 | 95.2 | OK | [symbol] | 12.45 | 91.58 | 12.11 | NG | NG |
| Ex-07 | HC-8 | 0.04 | P-3 | 200 | 0.38 | 91.13 | 85.4 | OK | 107.2 [symbol] | 0.84 | 91.11 | 0.46 | OK | Fair |
| Ex-08 | HC-8 | 0.04 | P-4 | 250 | 0.38 | 90.15 | 88.4 | OK | 97.520 | 0.58 | 90.00 | 0.20 | OK | Fair |
| Ex-09 | HC-9 | 0.10 | P-5 | 110 | 0.74 | 88.62 | 87.9 | OK | [symbol] | 0.68 | 88.85 | −0.06 | OK | OK |
| Ex-10 | HC-9 | 0.10 | P-6 | 150 | 0. [symbol] 1 | 88.65 | 80.6 | OK | 187.0 [symbol] | 0. [symbol] 1 | 88.91 | 0.20 | OK | OK |
| Ex-11 | HC-10 | 0.20 | P-6 | 150 | 0.57 | 87.4 [symbol] | 84.0 | OK | 478.384 | 0.85 | 87. [symbol] 6 | 0.2 [symbol] | OK | OK |

[symbol]

indicates data missing or illegible when filed

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed so be modified by the term “about.”

Furthermore, all publications and patents referenced hereto are incorporated by reference in their entirety to the same extent as if each individual publication or patent was specifically and individually indicated to be incorporated by reference. Various exemplary embodiments have been described. These and other embodiments are within the scope of the following claims.

1. A multilayer barrier film, comprising:
a hardcoat layer comprising nanoparticles hosted by a binder, the binder comprising one or more silicone (meth)acrylate additives; and
a barrier layer directly disposed on a major surface of the hardcoat layer.

2. The multilayer barrier film of claim 1, wherein the one or more silicone (meth)acrylate additives include polydimethylsiloxane (PDMS) acrylate, and the hardcoat layer comprises from about 0.01 wt % to about 10 wt % of the polydimethylsiloxane (PDMS) acrylate based on the total weight of the hardcoat layer.

3. The multilayer barrier film of claim 1, wherein the binder of the hardcoat layer further comprises cured acrylate formed by curing at least one of acrylic, (meth)acrylic oligomer, or monomer binder.

4. The multilayer barrier film of claim 1, wherein the hardcoat layer comprises from about 15 wt % to about 70 wt % of the binder and from about 30 wt % to about 85 wt % of the nanoparticles based on the total weight of the hardcoat layer.

5. The multilayer barrier film of claim 1, wherein the nanoparticles comprise from about 10 wt % to 50 wt % of a first group of nanoparticles having an average particle diameter in a range from 2 nm to 200 nm, and from about 50 wt % to about 90 wt % of a second group of nanoparticles having an average particle diameter in a range from 60 nm to 400 nm.

6. The multilayer barrier film of claim 5, wherein the ratio of average particle diameters of the first group of nanoparticles and the second group of nanoparticles is in a range from 1:2 to 1:200.

7. The multilayer barrier film of claim 1, wherein the barrier layer comprises a random covalent network containing silicon and one or more of carbon, oxygen, nitrogen, hydrogen and fluorine.

8. The multilayer barrier film of claim 1, wherein the barrier layer is a layer of diamond-like glass (DLG) material.

9. The multilayer barrier film of claim 1, further comprising a substrate, and the hardcoat layer being disposed between the substrate and the barrier layer.

10. A device comprising the multilayer barrier film of claim 1, the device further comprising a cover panel and an optically clear adhesive layer, the multilayer barrier film is disposed between the cover panel and the optically clear adhesive layer, and configured to prevent diffusion of moisture or oxygen from the cover panel to the optically clear adhesive layer.

11. A method of making a multilayer barrier film, the method comprising:
providing a mixture comprising nanoparticles and one or more curable binder materials;
curing the binder materials to provide a hardcoat layer, the hardcoat layer comprising the nanoparticles hosted by the binder, the binder further comprising one or more silicone (meth)acrylate additives; and
providing a barrier layer directly disposed on the hardcoat layer.

12. The method of claim 11, wherein the barrier layer is formed by ion-enhanced plasma chemical vapor deposition.
